(19) United States
(12) Patent Application Publication
(10) Pub. No.: US 2006/0274802 A1
(43) Pub. Date: Dec. 7, 2006

(54) Semiconductor optical device and module using the same

(76) Inventors: Masahiro Aoki, Kokubunji (JP); Etsuko Nomoto, Sagamihara (JP)

Correspondence Address: REED SMITH LLP, Suite 1400, 3110 Fairview Park Drive, Falls Church, VA, 22042, US

(21) Appl. No.: 11/203,304

(22) Filed: Aug. 15, 2005

(30) Foreign Application Priority Data
Jun. 3, 2005 (JP) 2005-163576

(51) Int. Cl. H01S 5/00

(52) U.S. Cl. 372/45.01; 372/50.12; 372/50.121

(57) ABSTRACT

A semiconductor laser device capable of providing high output power operation is provided which has a structure in which high output power and kink suppression can be simultaneously attained as well as these characteristics can be realized by a short chip length. In a waveguide structure of an MMI laser diode, a taper waveguide is intentionally inserted between a single mode waveguide and a multimode waveguide, and further, a single mode waveguide is used as a passive waveguide. These individual units or combination thereof can solve the above-described problems.

### CLAIM OF PRIORITY

The present application claims priority from Japanese application JP 2005-163576, filed on Jun. 3, 2005, the content of which is hereby incorporated by reference into this application.

### BACKGROUND OF THE INVENTION

1. Field of the Invention

The present invention relates to a semiconductor optical device and a module using the same technologies. More specifically, the present invention relates to a light source of a semiconductor optical device that stably operates at high optical output power suitable for an information processing terminal or for optical communication.

2. Description of the Related Arts

A technical difficulty in realizing a high power semiconductor laser diode is a permanent problem irrespective of application fields. According to respective application fields, research and development of high power laser diodes with various wavebands are still performed energetically. These high power semiconductor laser diodes can be structurally classified roughly into a single lateral mode laser diode and a multi lateral mode laser diode, in view of a waveguide lateral mode. In the single lateral mode laser diode, a lateral width of the laser waveguide must be generally set to a small value such as a cutoff width or less where a higher-order lateral mode is not allowed. Therefore, an upper limit is caused in a volume of an active layer, which causes direct restriction on development of a high power laser. More specifically, a width of the active layer in the laser waveguide is limited to a width of as narrow as about 2 to 3 μm or less. Accordingly, a current capable of being injected to the laser diode is limited to a certain low degree of value. As a result, a limit is caused in the optical output power. The simplest method for improving a saturation optical output power level by allowing a high injection current is to increase the lateral width of the laser waveguide. However, this method contradicts the restrictions for realizing the above-described single lateral mode waveguide. Therefore, the fact is that a technical limit is found in realization of the high power laser diode. Examples of such a high power semiconductor laser diode with the single lateral mode waveguide include an excitation light source, an optical disk writing light source and a printer light source for use in a fiber optical amplifier.

A known example of the laser waveguide structure which overcomes the trade-off between the lateral mode and the high output power includes an MMI waveguide structure using a multimode interference effect. This example is disclosed, for example, in 2004 IEEE 19^{th} International Semiconductor Laser Conference Digest (page 24) shown in FIG. 1 or in U.S. Pat. No. 3,244,115. The laser waveguide structure has the following characteristics. First, even in the case where the laser waveguide includes a waveguide that allows a multimode, when the waveguide is operated as the MMI waveguide, automatic output concentration in the single lateral mode waveguide which is set on the output side is allowed in terms of a primary principle. Therefore, the limit of the saturation injection current value is relaxed so that realization of a high power laser diode by a high current injection can be attained. Secondary, the structure includes a multimode interference waveguide region where light confinement is extremely strong. Therefore, the threshold current density is drastically reduced. In addition, an overlap integral of an electric field and light within the laser increases so that electro-optical conversion efficiency may be improved as compared with that of a normal single lateral mode laser.

Further, a known example of a device structure that realizes a tunable laser having high output power and excellent wavelength stability includes a structure formed by combining a multimode interference waveguide active layer and a distributed reflector waveguide of a single lateral mode. This example is disclosed, for example, in Japanese Patent Laid-open No. 2003-289169. Further, a known example of a manufacturing method of a device structure includes a method for realizing a preferable buried shape of a buried-heterostructure multimode interference laser diode. This example is disclosed, for example, in Japanese Patent Laid-open No. 2003-289169.

On the other hand, these new waveguide structures are not necessarily established technically in view of practical use. When manufacturing of a high power laser diode not using an MMI waveguide but using a current single lateral mode waveguide, the following method is employed. That is, a longer laser resonator is used and an active layer volume of the laser waveguide is increased in order to attain high power of the laser. FIG. 2 shows a trend between an optical output power of a semiconductor laser diode for use in optical recording as an example and a laser resonator length (a chip size) for attaining the output power. The data are created in the early part of 2005 when the present invention is carried out. The data show the following fact. That is, high power of a laser is demanded to improve a writing speed of an optical recording disk and therefore, an increase in laser resonator length is absolutely necessary to attain the high power. In this case, there is a problem in that the increase in chip size incurs a rise in chip cost. This is because in an optical disk light source promoting lower cost, the cost is almost controlled by the chip size that determines the number of devices obtained from a finite GaAs substrate, as shown in the upper axis of FIG. 2.

For an optical recording disk, an audio CD, a video CD or a Digital Versatile Disk (DVD) for large data recording is recently in widespread use in addition to a conventional compact disk (CD) that is developed mainly for recording music or data. Therefore, many disk drives normally have a structure having one disk drive adaptable to both of CD and DVD. In the structure, a 780-nm range CD semiconductor laser diode (hereinafter referred to as a “CD laser diode”) and a 650-nm range DVD semiconductor laser diode (hereinafter referred to as a “DVD laser diode”), which serve as heart parts of the drives, are manufactured on the same gallium arsenic (GaAs) substrate. For the purpose of realizing the structure, a monolithic two-wavelength laser diode is recently developed by monolithically integrating both of the CD laser diode and the DVD laser diode. The developing of this laser diode provides the following advantages. That is, since a two-wavelength optical system is simplified, a pick-up portion of the laser can be miniaturized. Further, since both of the CD laser diode and the DVD laser diode are mounted on the same substrate, essential reduction in chip area can be realized. An emitting layer of the laser diode uses the following materials. Aluminum gallium arsenide (AlGaAs) are used for the CD laser diode. Aluminum gallium indium phosphide (AlGaInP) are used for the DVD laser diode. However, due to difference in the electro-optic properties of the materials, it is more difficult for the latter AlGaInP DVD laser diode to realize a high power. Therefore, as shown in FIG. 2, the CD laser diode is shorter than the DVD laser diode in the laser chip size which is required to attain the same optical output power, and the difference in the laser chip size is as large as about 400 μm in a 200-mW class laser diode.

For the monolithic two-wavelength laser diode, it could be conceivable that the number of combinations of optical output power of the CD laser diode and the DVD laser diode according to selection of read and write functions of CD and DVD is four as below. At present, the combination (4) already penetrates the market. In particular, the combinations (1) and (2) are still in a research and development stage.

(1) CD high output power (reading & writing)+DVD high output power (reading & writing)

(2) CD low output power (only reading)+DVD high output power (reading & writing)

(3) CD high output power (reading & writing)+DVD low output power (only reading)

(4) CD low output power (only reading)+DVD low output power (only reading)

Incidentally, examples of documents on the monolithic two-wavelength laser diode include 2004 IEEE 19^{th} International Semiconductor Laser Conference Digest (page 123).

### SUMMARY OF THE INVENTION

In the conventional examples disclosed in 2004 IEEE 19^{th} International Semiconductor Laser Conference Digest or in U.S. Pat. No. 3,244,115, improvement of high output power by introduction of the MMI waveguide is already attained. However, these structures have the following problems. Therefore, it is still the case where the structures are not always in practical use in a wide range.

A first problem is difficulty of suppressing scattering and reflection of light waves caused by a rapid change of a waveguide width at the border between a multimode waveguide region and a single mode waveguide region. It is impossible to completely suppress the scattering and reflection of light waves at this site. However, it is required to minimize the scattering and reflection. In particular, when the reflected light returns to the inside of a laser resonator, a combined resonance is formed. As a result, an oscillation mode becomes unstable and therefore a structure capable of automatically preventing this problem is required.

A second problem is a difference between optical power density in the multimode waveguide region and that in the single mode waveguide region. The optical power density in the single mode waveguide region is about several times or more higher than that in the multimode waveguide region in which laser internal light is distributed in a wide range. Therefore, a high power laser diode of about several hundreds mW or more which is a typical applicable example of the MMI laser diode has the following problems. That is, a high power operation of the laser diode is limited due to reliability deterioration accompanying a crystal breakdown in the single mode waveguide region or due to an optical non-linear phenomenon caused by, for example, lateral hole burning.

In the meantime, the monolithic two-wavelength laser diode described in the foregoing section also has the following problems. Among four applications of the monolithic two-wavelength laser diode, the applications (1) and (2) each have important positions in an optical disk field such as computer applications or audio-video applications. In this case, since it is required that an AlGaInP DVD laser diode with a high technical difficulty be allowed to have high output power and therefore, the DVD laser diode must be more increased in length. In the monolithic two-wavelength laser diode manufactured by a normal cleavage method, the CD laser diode and the DVD laser diode have the same resonator length. Therefore, in order to allow the DVD laser diode to have high output power, the CD laser diode must have an excessive length. As a result, there arise big problems in that performance of the CD laser diode is deteriorated as well as an increase in substrate area leads to economical inefficiency.

In order to solve the above-described problems, the present inventors have designed a taper MMI structure as described below. That is, in the waveguide structure of the MMI laser diode, a taper waveguide is intentionally inserted between the single mode waveguide and the multimode waveguide. As a result, light scattering and light reflection are reduced at this site as well as a primary laser vertical resonance mode is prevented from being unstable when an uncontrollable slight reflected light returns again to the inside of the laser resonator. Further, the present inventors have designed a laser diode structure as described below. That is, in the waveguide structure of the MMI laser diode, a single mode waveguide is used as a passive waveguide. As a result, the manufactured laser diode structure is suitable particularly for CD laser diodes or DVD laser diodes, in which the optical power density has a significant effect on device reliability. When these units are used individually or in combination thereof, a high output power and high reliability of the single lateral mode laser diode can be simultaneously realized. Further, the present inventors have found the following fact. That is, in the case of incorporating an optical reflecting mirror formed using a grating into a single mode waveguide, even when an operating temperature of devices changes, conditions hardly vary where a loss of the MMI waveguide is reduced. Based on this finding, the MMI laser diode having more excellent characteristics is realized.

Incidentally, in this MMI laser diode, high optical output power can be realized by a short laser resonator length. Therefore, when this laser diode is used, a variety of new high power laser diodes are realized. For example, in the case of monolithically integrating the MMI DVD laser diode and the CD laser diode, when using a conventional CD laser resonator length of about 1300 μm or less, a high output power of the MMI DVD laser diode can be realized. Further, also in the case of integrating a short resonator-type laser diode into a cheaper CD package, high output power of the laser diode can be attained without impairing a high power property.

According to the present invention, in the case of monolithically integrating the MMI DVD laser diode and the CD laser diode, when a conventional CD laser resonator length of about 1300 μm or less is used, high output power of the MMI DVD laser diode can be realized. Further, also in the case of integrating a short resonator-type laser diode into an inexpensive CD package, high output power of the laser diode can be attained without impairing a high power property.

### BRIEF DESCRIPTION OF THE DRAWINGS

FIG. 1 is a diagram showing a conventional MMI laser diode;

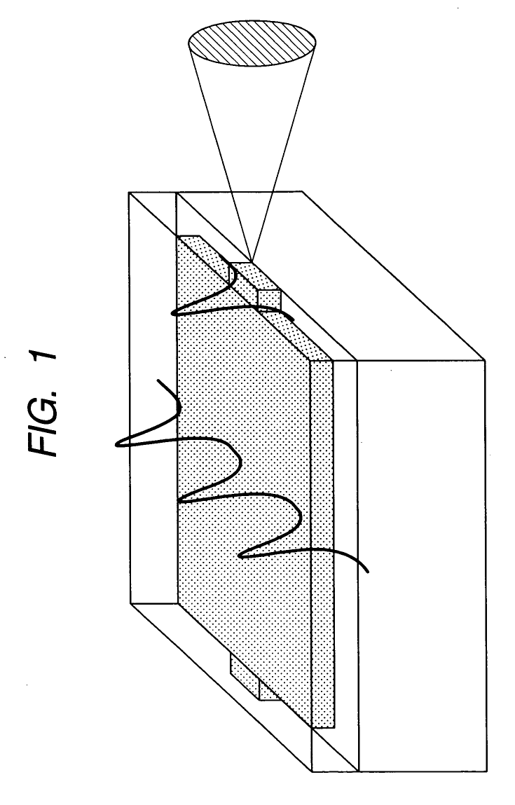

FIG. 2 is a diagram showing a trend between optical output power of a semiconductor laser diode for use in optical recording and a laser resonator length (a chip size) for attaining the output power;

FIG. 3A is a perspective view of an AlGaInP semiconductor laser diode according to a first embodiment of the present invention and FIG. 3B is a partial enlarged lateral view of the laser diode in FIG. 3A;

FIG. 4 is a top view of the AlGaInP semiconductor laser diode according to the first embodiment of the present invention;

FIG. 5 is a diagram showing a can module manufactured by integrating a laser device into a can type standard package;

FIG. 6A is a perspective view of an AlGaInP semiconductor laser diode according to a second embodiment of the present invention and FIG. 6B is a partial enlarged lateral view of the laser diode in FIG. 6A;

FIG. 7 is a top diagram of the AlGaInP semiconductor laser diode according to the second embodiment of the present invention;

FIG. 8 is a graph illustrating one example of results obtained by subjecting an effect of a taper MMI structure to simulation study;

FIG. 9 is a diagram showing a calculation example of a light intensity distribution within a conventional square MMI structure;

FIG. 10 is a diagram showing an analysis example of light wave propagation when a taper length is changed;

FIG. 11 is a perspective view of an AlGaInP semiconductor laser diode according to a third embodiment of the present invention;

FIG. 12 is a perspective view of an AlGaInP semiconductor laser diode according to a fourth embodiment of the present invention;

FIG. 13A is a perspective of an AlGaInP semiconductor laser diode according to a fifth embodiment of the present invention and FIG. 13B is a partial enlarged lateral view of the laser diode in FIG. 13A; and

FIG. 14 is a perspective view of the AlGaInP semiconductor laser diode according to the fifth embodiment of the present invention.

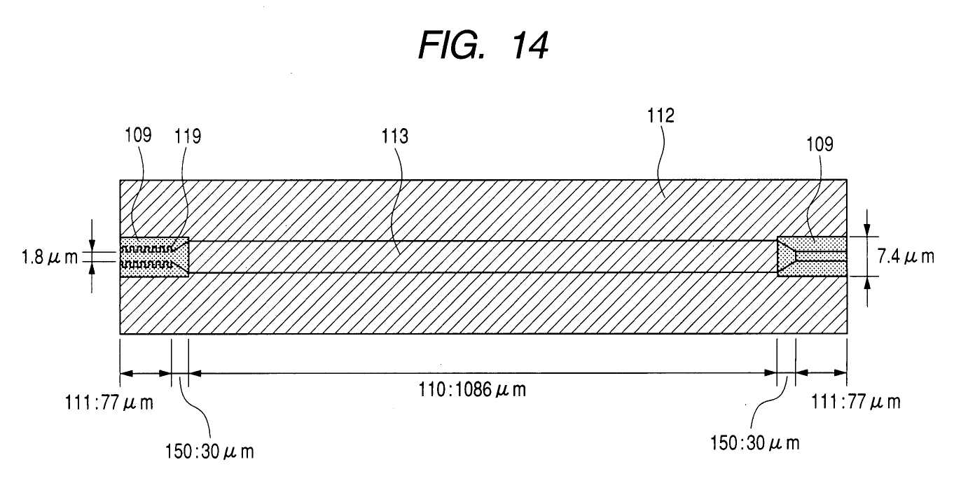

### DETAILED DESCRIPTION OF THE PREFERRED EMBODIMENTS

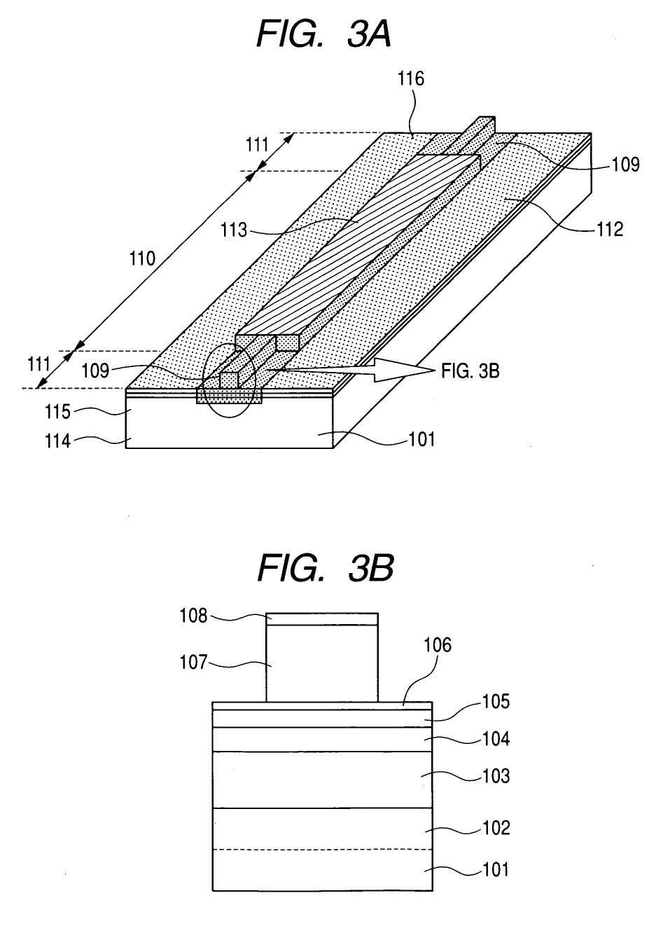

Preferred embodiments of the present invention will be described below with reference to FIGS. 3 to 12.

### First Embodiment

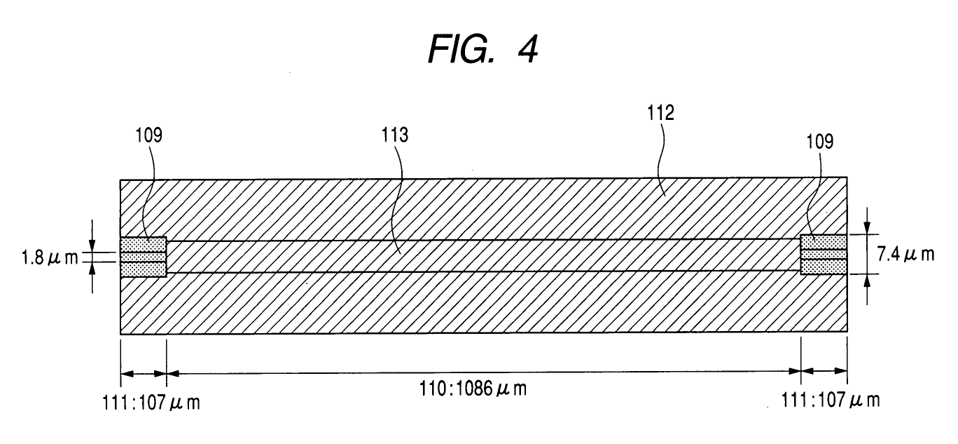

FIG. 3A is a perspective view of a 650-nm range high power DVD laser diode structure according to a first embodiment of the present invention, FIG. 3B is its partial enlarged lateral view and FIG. 4 is its top view.

On an n-type angled GaAs substrate 101 offset at 10 deg. from a (100) surface orientation, an n-type GaAs buffer layer 102 with a film thickness of 0.5 μm, an n-type AlGaInP cladding layer 103, a multi-quantum-well active layer 104, a first p-type AlGaInP cladding layer 105 with a film thickness of 0.05 μm, a p-type GaInP etching stop layer 106 with a film thickness of 5 nm, a second p-type AlGaInP cladding layer 107 with a film thickness of 1.5 μm, and a p+ type GaAs contact layer 108 with a film thickness of 0.2 μm are sequentially epitaxially grown by metalorganic vapor phase epitaxy (MOVPE). The Multi-quantum-well active layer 104 comprises three undoped compression strain GaInP quantum-well layers with a film thickness of 5 nm, four tensile strain AlGaInP quantum barrier layers with a film thickness of 4 nm, and upper and lower no strain AlGaInP photo-isolation confinement layers with a film thickness of 20 nm. Further, a light emission wavelength is set to about 650 to 660 nm.

Next, on the thus prepared semiconductor substrate, a desired diffusion mask is formed by a photolithography process. Thereafter, a ZnO solid diffusion source is deposited thereon and is subjected to heat treatment at a temperature of 500 to 600° C. Thus, a Zn diffusion region 109 is provided on a region that corresponds to each of both ends of a resonator, to be processed to each of single-lateral-mode-waveguides. After formation of the diffusion region, the diffusion source is removed. As a result, the Multi-quantum-well active layer 104 and upper and lower cladding layers 103, 105 and 107 in this region are intermixed by intermixing of group III constituent elements and changed into an AlGaInP mixed crystal of which the average composition corresponds to a composition with a band gap wavelength equivalent to about 590 nm. As a result, this region serves as a passive region. Thereafter, by a common method, the region is processed to a ridge stripe structure having an MMI waveguide pattern shown in FIG. 3. Through the photolithography process and the etching process, the layers 107 and 108 are etched and removed up to the layer 106 to form the ridge stripe structure. At this time, each dimension is determined such that a lateral width Wₘₘᵢ of a multi-lateral-mode-waveguide 110 and a length Lₘₘᵢ thereof almost satisfy the theoretical expression Lₘₘᵢ=nWₘₘᵢ²/λ. The specific design values of the width and length of the waveguide are experimentally determined such that a mode conversion loss within a combined waveguide is minimized, that is, Wₘₘᵢ=7.4 μm and Lₘₘᵢ=1086 μm. Further, in order to allow stabilization of the mode of a waveguide light converted from the mode of the multi-lateral-mode-waveguide 110 to the mode of the single-lateral-mode-waveguide 111 with a lateral width of 1.8 μm, the single-lateral-mode-waveguide length is set to 107 μm. As a result, the whole length of the laser diode is set to 1300 μm.

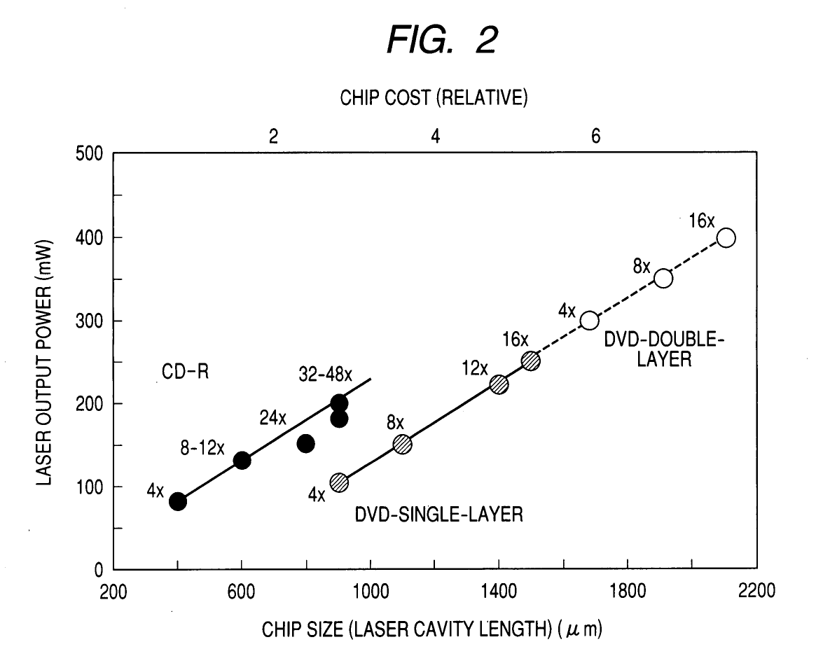

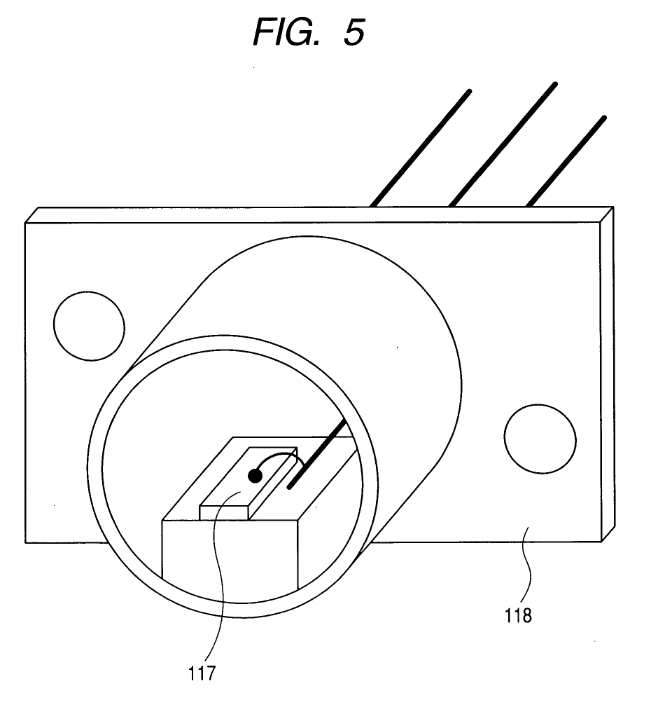

Next, a surface passivation film 112 is formed by a chemical deposition method. Subsequently, through a photolithography process and an etching process, grooves adapted to reduce the device capacity are formed on both sides of the stripe (not shown). After completion of an electrode window-opening process, a p-type electrode 113 and an n-type electrode 114 are deposited. Thereafter, a device is cut out by a cleavage scribe to form thereon facet coating films 115 and 116 having a predetermined reflection coefficient. The present device oscillates at a wavelength of 650 to 660 nm, and attains the kink-free maximum optical output power of 300 mW at a temperature of 80° C. This value is 50% larger than that of a simultaneously manufactured conventional device which is constituted only by the single-lateral-mode-waveguide. As understood from the relationship between the laser output power and chip size shown in FIG. 2, the present invention can realize a high power operation of 300 mW by about two-thirds of a conventional chip size. Accordingly, cost reduction can be realized by the cost of the reduced chip size. FIG. 5 is a diagram showing a can module manufactured by integrating the laser device 117 into a can type standard package 118. In the present laser device, the chip length can be shortened up to about 1300 μm. Therefore, the use of an inexpensive package normally used in a CD laser can module manufactured as a can module chassis using a molding press is enabled. The reason why a conventional device with a chip size of about 1300 μm or more cannot be incorporated into this standard cheap package is that the device protrudes from the inexpensive package. As a result, it is understood that reduction of the laser chip size is effective in the above-described cost reduction of the laser chip itself as well as in the cost reduction of can module parts. Incidentally, it is noted that the essence of the effect is present not in the MMI laser diode but in the small chip size.

### Second Embodiment

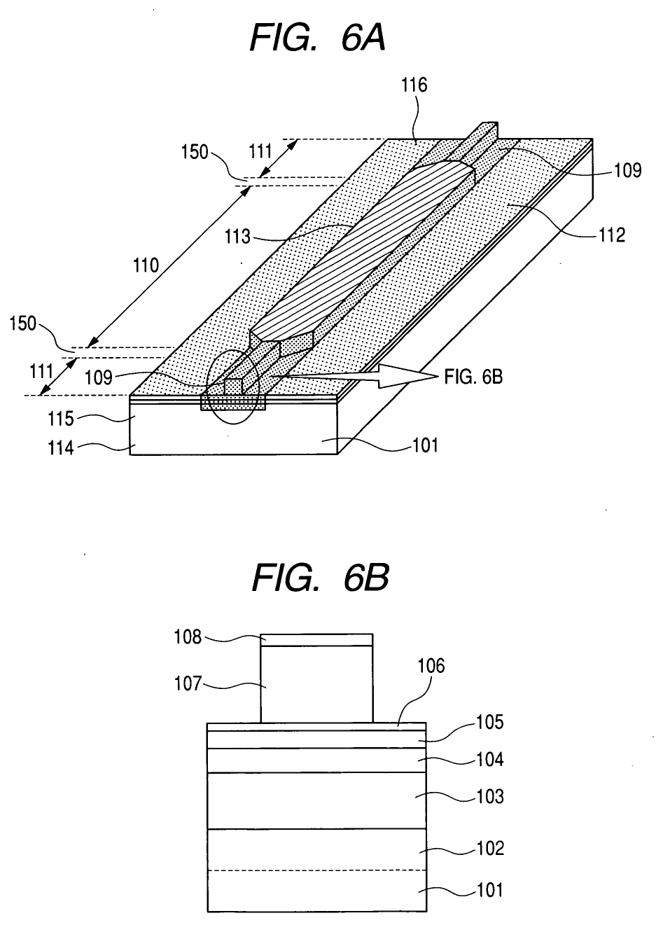

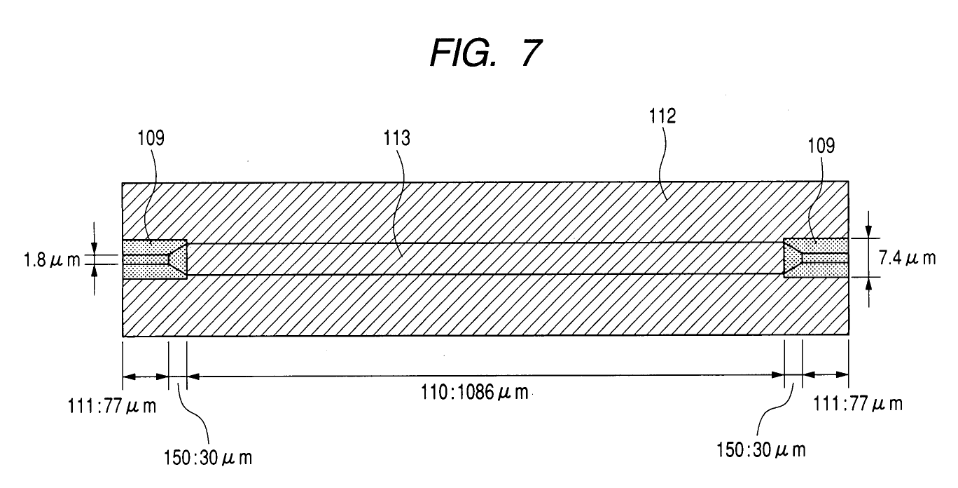

FIGS. 6A, 6B and 7 are diagrams showing a structure of a semiconductor laser diode according to a second embodiment of the present invention. The second embodiment differs from the first embodiment in a structure of the MMI waveguide; however, the semiconductor laminated structure of the semiconductor laser diode in the second embodiment is the same as that in the first embodiment. FIG. 6A is a perspective view showing a structure of a 650 nm range high power DVD laser diode. FIG. 6B is its partial enlarged view and FIG. 7 is its top view.

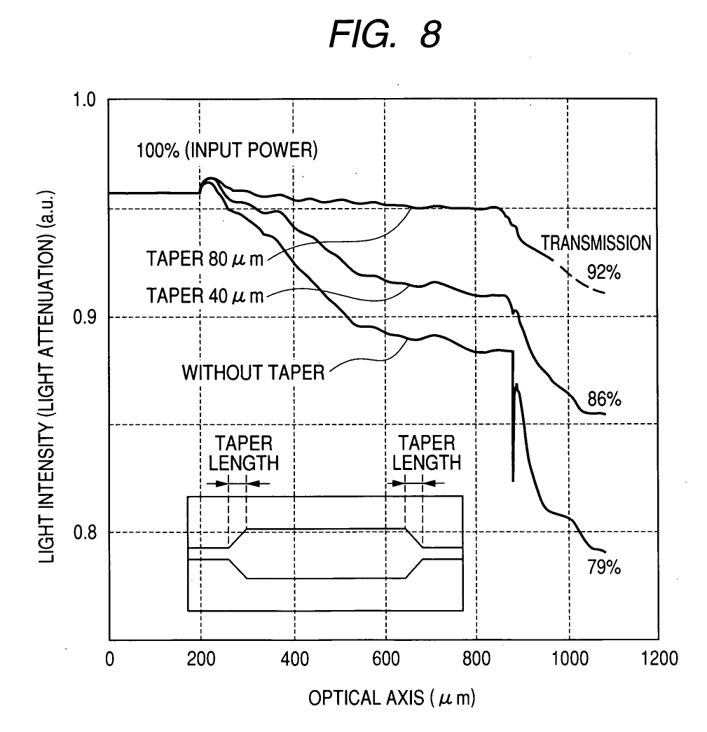

As shown in FIG. 7, the present embodiment provides a taper MMI structure as described below. That is, in the waveguide structure of the MMI laser diode, a taper waveguide 150 is intentionally inserted between a single mode waveguide and a multimode waveguide. As a result, light scattering and light reflection are reduced at this site as well as an original laser vertical resonance mode is prevented from being unstable when an uncontrollable slight reflected light returns again to the inside of the laser resonator. FIG. 8 is one example of results obtained by subjecting an effect of the taper MMI structure to simulation study. On the conventional square MMI structure having the same laser layer structure as that in the first embodiment and the taper MMI structure according to the second embodiment, waveguide loss for signal light with a wavelength of 650 nm is analyzed using a beam propagation method

In the figure, each line represents attenuation of light intensity due to the MMI effect. The attenuation from 100% as an idealized state of the light intensity on the output end side provides an indication of the waveguide loss. As understood from the figure, when the taper waveguide is not introduced, the light intensity is 79% (single path waveguide loss is 21%). To the contrary, when the taper waveguide is introduced, the light intensity is improved up to 92% (single path waveguide loss is 8%), and improvement of about 14% is observed. This value indicates a slight difference in terms of numerical values. However, since laser oscillates through multiple reflection between both of the ends, this value exhibits important improvement.

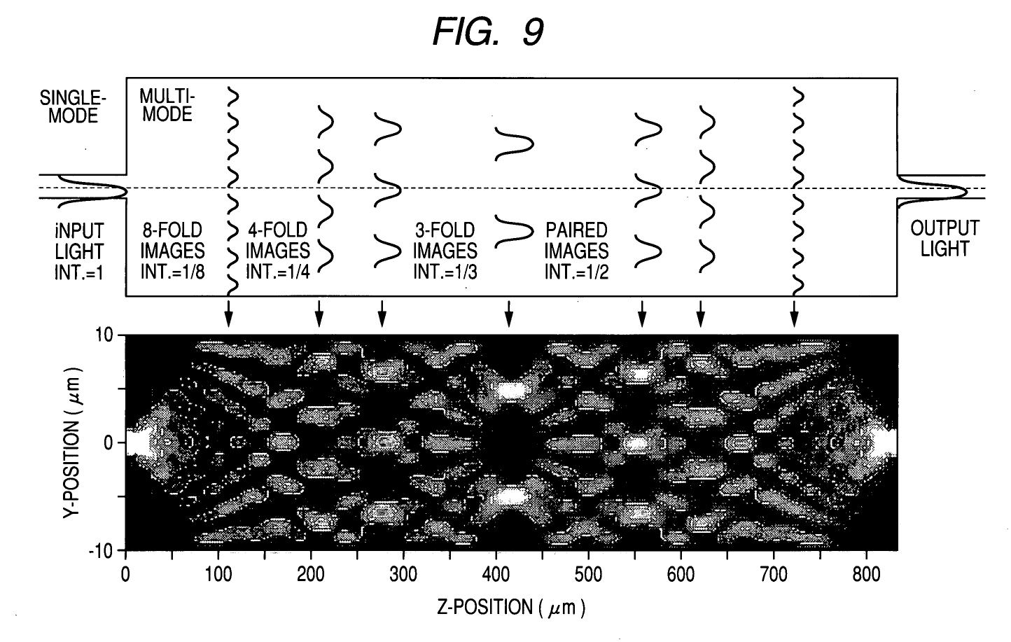

FIG. 9 shows a calculation example of a light intensity distribution within the conventional square MMI structure. Further, FIG. 9 shows a state where owing to the multimode interference effect, the light wave inputted from the single mode waveguide is concentrated in the output side single mode waveguide which is set at a predetermined position. The important point herein is that waveguide light is scarcely present in four corners of the square MMI shape. Accordingly, in the conventional square MMI structure, a laser driving current that flows through the four corners of the square MMI shape has no effect on the gain of a waveguide mode, and therefore, the current acts as a reactive current. The taper MMI structure proposed in the present invention is also effective in preventing the reactive current from occurring. Therefore, it is understood that this structure particularly contributes to improvement in the light emission efficiency of laser.

In a reflection of the above improvement effects, the device in the present embodiment attains the kink-free maximum optical output power of 350 mW at a temperature of 80° C. This value is about 17% larger than that of the device in the first embodiment.

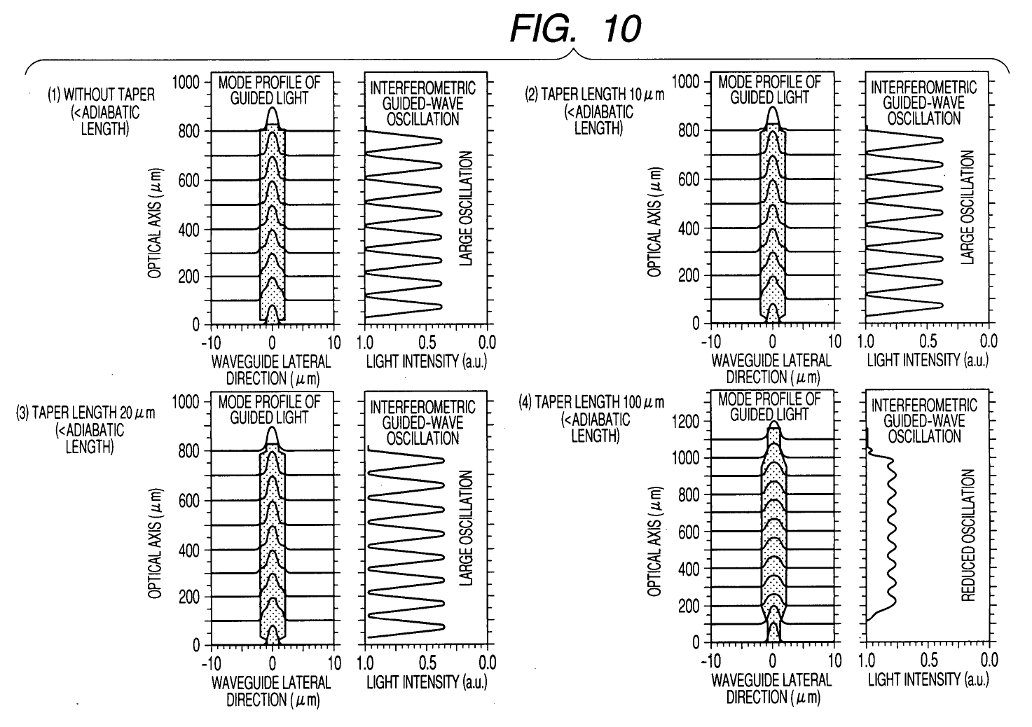

Next, a quantitative consideration on the set value of a taper length is described. FIG. 10 shows an example of analyzing, using a beam propagation method, light wave propagation when 0, 10, 20 and 100 μm are each given to the taper length Lₜₐₚₑᵣ. When the Lₜₐₚₑᵣ is 0, 10 or 20 μm, pulses of a guided light intensity due to the MMI effect are observed. To the contrary, when the Lₜₐₚₑᵣ is 100 μm, the pulses are extremely slightly observed as well as the single path waveguide loss is almost zero. This result indicates that the waveguide structure already loses the MMI effect.

In general, as the taper length is increased under the condition that a modulation width of waveguides is made constant, the conversion loss accompanying mode enlargement of guided light is negligibly reduced. The taper length at this time is generally called an adiabatic length. The length is a physical value uniquely fixed when the layer structure and modulation width of waveguides are determined. In the example of FIG. 10, it is highly probable that the taper length Lₜₐₚₑᵣ of 100 μm is already in excess of the adiabatic length. Therefore, it is understood that setting of the taper length Lₜₐₚₑᵣ in this region is inappropriate for the design of the MMI structure. Accordingly, it is noted that in the taper MMI laser diode proposed in the present invention, the taper length must be set to a value smaller than the adiabatic length.

### Third Embodiment

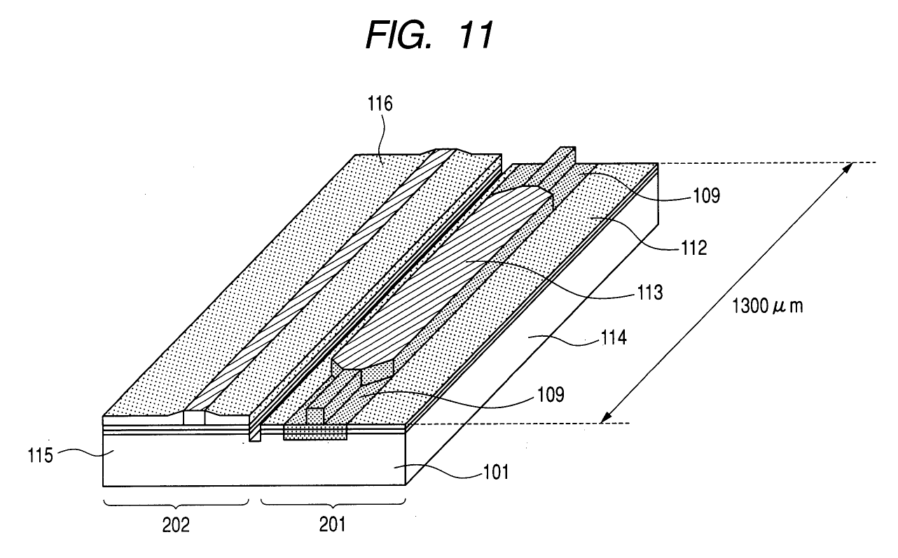

FIG. 11 is a perspective view of a monolithic two-wavelength laser diode manufactured by monolithically integrating a 650-nm range high power DVD laser diode 201 and a 780-nm range high power CD laser diode 202 according to a third embodiment of the present invention. Herein, the DVD laser diode has the same structure as the taper MMI laser diode shown in the second embodiment and has a resonator length of 1300 μm. On the other hand, the CD laser diode is a known AlGaAs buried ridge type laser diode and has a normal single-mode-waveguide structure. At a temperature of 80° C., the DVD laser diode attains a kink-free maximum optical output power of 350 mW and the CD laser diode attains a kink-free maximum optical output power of 250 mW. These values are suited to DVD double-layer eightfold-speed writing and CD single-layer forty eight-fold speed writing.

### Fourth Embodiment

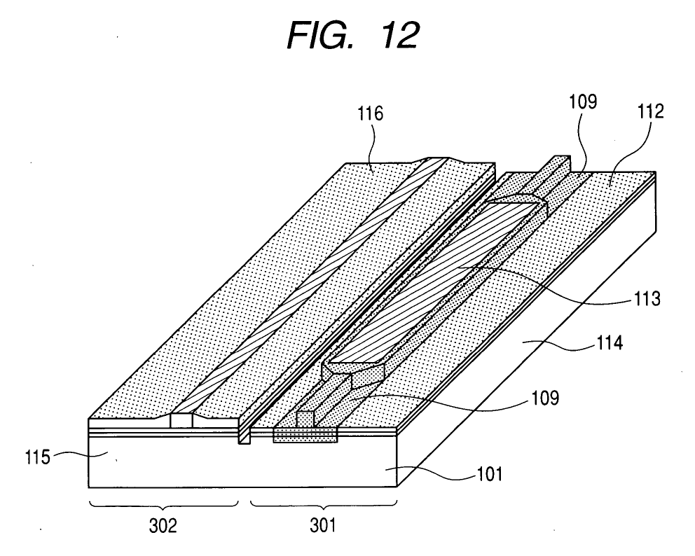

FIG. 12 is a perspective view of a monolithic two-wavelength laser diode manufactured by monolithically integrating a 650-nm range high power DVD laser diode 301 and a 780-nm range low power CD laser diode 302 according to a fourth embodiment of the present invention. Herein, the DVD laser diode is a taper MMI laser diode. In the laser diode, the lateral width and the length are set to Wₘₘᵢ=5.4 μm and Lₘₘᵢ=578 μm, respectively, and the resonator length is as extremely small as 800 μm. On the other hand, the CD laser diode is a known AlGaAs buried ridge type laser diode and has a normal single-mode-waveguide structure. At a temperature of 80° C., both of the DVD laser diode and the CD laser diode attain the kink-free maximum optical output power of 150 mW. These values are suited to DVD eightfold-speed writing and CD twenty-fourfold-speed writing. Further, this device is mounted on a CD can module manufactured using a molding press.

### Fifth Embodiment

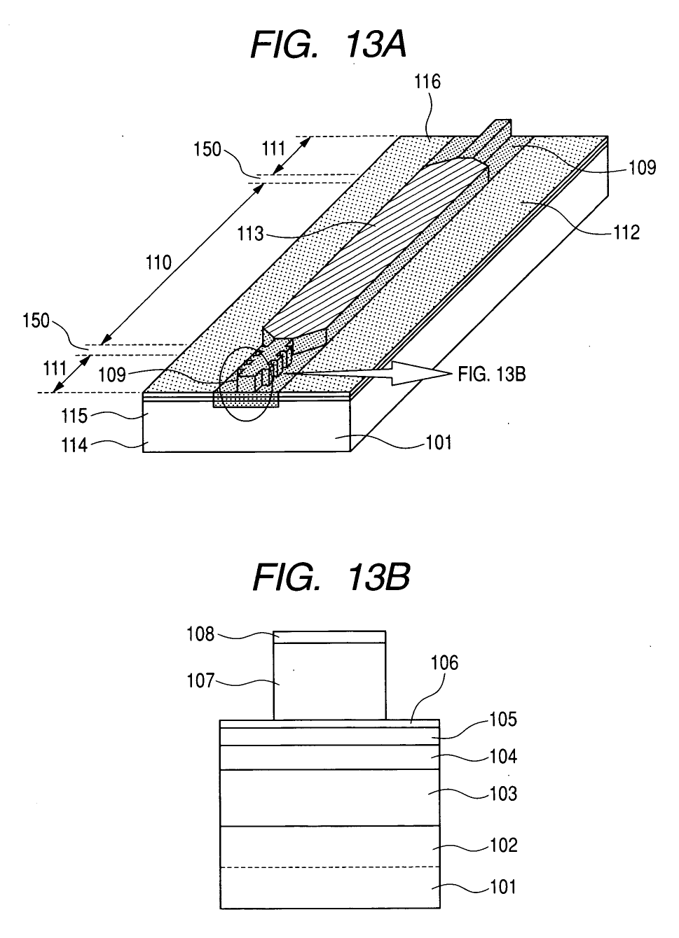

FIG. 13A is a perspective view of a 650-nm range high power DVD laser diode according to a fifth embodiment of the present invention and FIG. 13B is its partial enlarged lateral view. The device structure itself is the same as that described in the second embodiment except the following points. A left front site in FIG. 13A shows a light emitting end. On a single-mode-waveguide at this site, there is formed a lateral width modulation-type grating where a lateral width of the waveguide is modulated in the optical axis direction at the period of 201 nm. The period 201 nm of the lateral width modulation-type grating provides a secondary diffraction mirror for a 650-nm range laser diode oscillation light. Herein, reflectance of the diffraction mirror is set to about 6% by controlling a length of the grating region and a depth of the lateral width modulation through a lithography process by electron beam exposure and through a vertical dry etching process.

Further, at room temperature, a gain peak wavelength of an active layer is set to an about 10 nm short wavelength side as compared with a black wavelength determined by the lateral width modulation-type grating. That is, the so-called detuning amount, which is a difference between both the wavelengths, is set to a positive value. As s result, the device according to the fifth embodiment is improved, particularly, in the current-optical output power characteristics at higher temperatures as compared with that in the second embodiment. In the device structure according to the fifth embodiment, the oscillation wavelength is set to a level near the black wavelength of the lateral width modulation-type grating. On the other hand, since the resonator of the device structure according to the second embodiment has a Fabri-Perot resonator structure, the oscillation wavelength is set to a level near the gain peak of the light emitting layer. As described above, on this occasion, in the MMI conditional expression Lₘₘᵢ=nWₘₘᵢ²/λ, both of an effective diffraction index n and oscillation wavelength λ in the waveguide independently vary with changes in temperature.

Therefore, deviation from the MMI conditional expression accompanying the temperature change is relatively large. On the other hand, in the device structure according to the fifth embodiment, the oscillation wavelength λ (n₀ denotes an effective refractive index of a light emitting side single-mode-waveguide, and Λ denotes a period of a secondary grating) is determined by an expression λ=n₀Λ and further no determines the temperature change of the oscillation wavelength. Herein, since the temperature change of n₀ and n is almost the same, the change in a denominator and numerator of the MMI conditional expression Lₘₘᵢ=nWₘₘᵢ²/λ=nWₘₘᵢ²/n₀Λ is almost canceled. As a result, deviation of the MMI conditions against the temperature change is negligibly reduced. This device structure has further advantages as described below. By employing a positive detuning amount at room temperature, the detuning amount change at a high temperature can be reduced. As a result of combining these advantages, the MMI laser diode proposed in the present invention has a structure as described below. That is, even when a temperature rises to create an environment where the oscillation property of the laser diode readily deteriorates, a more preferable output property is obtainable.

In the present embodiment, the lateral width modulation-type secondary grating is used for the sake of convenience. As would be obvious to one skilled in the art, even when using a primary grating or a grating two-dimensionally drawn within a normal layer, the same effect is obtained.

In the above five embodiments, applicable examples of the present invention mainly to the semiconductor laser diode for use in optical disks are described. It is noted that the present invention is applicable not only to a semiconductor laser diode for use in optical disks but also to an arbitrary waveguide-type semiconductor laser diode.

Incidentally, a description will be made of reference numerals used in the figures of this application as below.

101 . . . N-type angled GaAs substrate, 102 . . . N-type GaAs buffer layer, 103 . . . N-type AlGaInP cladding layer, 104 . . . Multi-quantum-well active layer, 105 . . . First p-type AlGaInP cladding layer, 106 . . . P-type GaInP etching stop layer, 107 . . . Second p-type AlGaInP cladding layer, 108 . . . P+ type GaAs contact layer, 109 . . . Zn diffusion region, 110 . . . Multi-lateral-mode-waveguide, 111 . . . Single-lateral-mode-waveguide, 112 . . . Surface passivation film, 113 . . . P-type electrode, 114 . . . N-type electrode, 115 . . . Facet coating film, 116 . . . Facet coating film, 117 . . . Present laser device, 118 . . . Can type standard package, 150 . . . Taper waveguide, 201 . . . 650-nm range high power DVD laser diode, 202 . . . 780-nm range high power CD laser diode, 301 . . . 650-nm range high power DVD laser diode, 302 . . . 780-nm range low power CD laser diode.

What is claimed is:

1. A Fabri-Perot resonator type semiconductor optical device comprising:
a semiconductor substrate;
a core region formed on the semiconductor substrate; and
a cladding region provided on at least one of a surface of the core region on the semiconductor substrate side or a surface of the core region on a side opposite to the semiconductor substrate, at least one of the core region or the cladding region having a stripe waveguide;
wherein the waveguide is composed of a combined waveguide comprising:
a single-lateral-mode-waveguide whose lateral width within a gain region of the waveguide is set to a value narrower than a cutoff width where oscillated light has a single lateral mode; and
a multi-lateral-mode-waveguide whose lateral width within a gain region is set to a value wider than the cutoff width, the single-lateral-mode-waveguides being connected to both ends of the multi-lateral-mode-waveguide; and
wherein the single-lateral-mode-waveguide comprises a passive region, and
the lateral width and optical axial length of the multi-lateral-mode-waveguide are set so that a mode conversion loss within the combined waveguide may be a predetermined amount.

2. A semiconductor optical device comprising:
a semiconductor substrate;
a core region formed on the semiconductor substrate; and
a cladding region provided on at least one of a surface of the core region on the semiconductor substrate side or a surface of the core region on a side opposite to the semiconductor substrate, at least one of the core region or the cladding region having a stripe waveguide;
wherein the waveguide is composed of a combined waveguide comprising:
a single-lateral-mode-waveguide whose lateral width within a gain region of the waveguide is set to a value narrower than a cutoff width where oscillated light has a single lateral mode; and
a multi-lateral-mode-waveguide whose lateral width within a gain region is set to a value wider than the cutoff width, the single-lateral-mode-waveguides being connected to both ends of the multi-lateral-mode-waveguide; and
wherein a taper region varying in a lateral width of the waveguide is provided in a connection region between the single-lateral-mode-waveguide and the multi-lateral-mode-waveguide, and
the lateral width and optical axial length of the multi-lateral-mode-waveguide are set so that a mode conversion loss within the combined waveguide may be a predetermined amount.

3. The semiconductor optical device according to claim 2, wherein an optical axial length of the taper region is shorter than an adiabatic length which is a shortest taper length adapted to smoothly attain a mode conversion in the taper region.

4. A semiconductor optical device comprising:
a semiconductor substrate;
a core region formed on the semiconductor substrate; and
a cladding region provided on at least one of a surface of the core region on the semiconductor substrate side or a surface of the core region on a side opposite to the semiconductor substrate, at least one of the core region or the cladding region having a stripe waveguide;
wherein the waveguide is composed of a combined waveguide comprising:
a single-lateral-mode-waveguide whose lateral width within a gain region of the waveguide is set to a value narrower than a cutoff width where oscillated light has a single lateral mode; and
a multi-lateral-mode-waveguide whose lateral width within a gain region is set to a value wider than the cutoff width, the single-lateral-mode-waveguides being connected to both ends of the multi-lateral-mode-waveguide; and
wherein the single-lateral-mode-waveguide comprises a passive region, and
a taper region varying in the lateral width of the waveguide is provided in a connection region between the single-lateral-mode-waveguide and the multi-lateral-mode-waveguide,
the lateral width and optical axial length of the multi-lateral-mode-waveguide are set so that a mode conversion loss within the combined waveguide may be a predetermined amount, and
an optical axial length of the taper region is shorter than an adiabatic length which is a shortest taper length adapted to smoothly attain a mode conversion in the taper region.

5. The semiconductor optical device according to claim 2, wherein any one of the single-lateral-mode-waveguides connected to both ends of the multi-lateral-mode-waveguide is a waveguide having formed thereon a lateral width modulation-type grating where the lateral width of the waveguide is modulated in an optical axis direction at a predetermined period.

6. A semiconductor laser diode having a waveguide structure of the semiconductor optical device according to claim 1.

7. A semiconductor laser diode having a waveguide structure of the semiconductor optical device according to claim 2.

8. A semiconductor laser diode having a waveguide structure of the semiconductor optical device according to claim 4.

9. A semiconductor laser diode according to claim 4, which has a waveguide structure in which the whole length of the laser diode in a resonator direction is 1300 μm or less.

10. A semiconductor laser diode according to claim 5, which has a waveguide structure in which the whole length of the laser diode in a resonator direction is 1300 μm or less.

11. A semiconductor laser diode according to claim 6, which has a waveguide structure that the whole length of the laser diode in a resonator direction is 1300 μm or less.

12. A semiconductor laser diode, which is a monolithic multi-wavelength laser diode that outputs within the same chip a plurality of laser beams having respective wavelengths different from each other,
wherein at least one of the plurality of laser diodes has the waveguide structure according to claim 4.

13. A semiconductor laser diode, which is a monolithic multi-wavelength laser diode that outputs within the same chip a plurality of laser beams having respective wavelengths different form each other,
wherein at least one of the plurality of laser diodes has the waveguide structure according to claim 5.

14. A semiconductor laser diode, which is a monolithic multi-wavelength laser diode that outputs within the same chip a plurality of laser beams having respective wavelengths different from each other,
wherein at least one of the plurality of laser diodes has the waveguide structure according to claim 6.

15. A semiconductor laser diode, which is a monolithic two-wavelength laser diode comprising:
a single substrate; and
a 780-nm range laser diode and a 650-nm range laser diode mounted on the single substrate;
wherein the 650-nm range laser diode has a waveguide structure of the semiconductor optical device according to claim 7.

16. A semiconductor laser diode, which is a monolithic two-wavelength laser diode comprising:
a single substrate; and
a 780-nm range laser diode and 650-nm range laser diode mounted on the single substrate;
wherein the 650-nm range laser diode has a waveguide structure of the semiconductor optical device according to claim 8.

17. A semiconductor laser diode, which is a monolithic two-wavelength laser diode comprising:
a single substrate; and
a 780-nm range laser diode and a 650-nm range laser diode mounted on the single substrate;
wherein the 650-nm range laser diode has a waveguide structure of the semiconductor optical device according to claim 9.

18. A semiconductor laser module comprising the semiconductor optical device according to claim 1 mounted on a standard can package for use in a compact disk semiconductor laser diode.

19. A semiconductor laser module comprising the semiconductor optical device according to claim 2 mounted on a standard can package for use in a compact disk semiconductor laser diode.

20. A semiconductor laser module comprising the semiconductor optical device according to claim 4 mounted on a standard can package for use in a compact disk semiconductor laser diode.
